(19) United States
(12) Patent Application Publication
(10) Pub. No.: US 2009/0321920 A1
(43) Pub. Date: Dec. 31, 2009

(54) Semiconductor device and method of manufacturing the same

(75) Inventors: Shinichi Sakurada, Tokyo (JP); Fumitomo Watanabe, Tokyo (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: Elpida Memory, Inc., Tokyo (JP)

(21) Appl. No.: 12/457,495

(22) Filed: Jun. 12, 2009

(30) Foreign Application Priority Data
Jun. 25, 2008 (JP) P2008-165720

(51) Int. Cl. H01L 23/48; H01L 21/56

(52) U.S. Cl. 257/698; 438/124; 257/E23.011; 257/E21.502; 257/E21.499

(57) ABSTRACT

A semiconductor device includes: a substrate; a plurality of connection pads provided on the substrate; a semiconductor chip; a plurality of electrode pads provided on the semiconductor chip; a plurality of wires electrically connecting the connection pads and the electrode pads; and a seal covering the semiconductor chip and the wires. The semiconductor chip is distanced from the substrate while being placed inside a periphery of the substrate. The seal intervenes between the semiconductor chip and the substrate.

### BACKGROUND OF THE INVENTION

1. Field of the Invention

The present invention relates to a semiconductor device including a semiconductor chip mounted on a wiring substrate and a method of manufacturing the same.

Priority is claimed on Japanese Patent Application No. 2008-165720, filed Jun. 25, 2008, the content of which is incorporated herein by reference.

2. Description of the Related Art

Conventionally, a BGA (Ball Grid Array)-type semiconductor device includes: a wiring substrate, on a top surface of which multiple connection pads are provided, and a bottom surface of which multiple lands are provided to be electrically connected to the connection pads; a semiconductor chip provided on the top surface of the wiring substrate; wires electrically connecting electrode pads provided on the semiconductor chip and the connection pads provided on the wiring substrate; a seal which is made of insulating resin and covers at least the semiconductor chip and the wires; and external terminals (solder balls) provided on the lands. For example, Japanese Unexamined Patent, First Publication Nos. 2001-44229 and 2001-44324 disclose such a conventional semiconductor device.

Additionally, Japanese Unexamined Patent, First Publication No. S59-89423 or S62-92331 discloses a semiconductor device including a semiconductor chip which is not fixed on a wiring substrate. Specifically, a semiconductor chip is provided in an opening formed in a wiring substrate while being suspended from the wiring substrate through wires. Then, the semiconductor chip, the wires, and a part of the wiring substrate are sealed by liquid resin.

However, in the semiconductor device disclosed in Japanese Unexamined Patent, First Publication Nos. 2001-44229 and 2001-44324, the difference in thermal expansion coefficients between the semiconductor chip and the wiring substrate causes stress since the semiconductor chip is fixed on the wiring substrate, thereby degrading the reliability of the semiconductor device.

Additionally, stress is focused on the boundary between a region of the wiring substrate where the semiconductor chip is mounted and the other region of the wiring substrate, especially on four corners of the semiconductor chip. Consequently, external terminals (solder balls) provided under the stress-focused region damage, thereby degrading the reliability of secondary mounting of the semiconductor device.

Further, the difference in thermal expansion coefficients between the semiconductor chip and the wiring substrate causes warpage of the semiconductor device, thereby degrading the mounting precision of the semiconductor device and connection defects of solder balls.

In the semiconductor device disclosed in Japanese Unexamined Patent, First Publication No. S59-89423 or S62-92331, an opening larger than the semiconductor chip is provided in the wiring substrate to provide the semiconductor chip therein, thereby preventing miniaturization of the semiconductor device. Therefore, demands for miniaturization of semiconductor devices with the recent miniaturization of mobile devices cannot be fulfilled.

Additionally, the greater number of terminals are provided, the larger the wiring substrate becomes due to wiring drawing and the like, thereby making the semiconductor device larger. Since the opening is larger than the semiconductor chip, the wiring substrate becomes larger, resulting in higher manufacturing costs.

Further, the bottom surface of the semiconductor chip is not covered by the seal resin, thereby degrading the humidity resistance or the mechanical strength of the semiconductor device.

Moreover, the liquid resin is provided for each product by, for example, potting, thereby degrading the manufacturing efficiency and making a shape of the semiconductor device unstable. Consequently, positioning of the semiconductor device is difficult, and identification marks cannot clearly be formed on the seal.

### SUMMARY

In one embodiment, there is provided a semiconductor device including: a substrate; a plurality of connection pads provided on the substrate; a semiconductor chip; a plurality of electrode pads provided on the semiconductor chip; a plurality of wires electrically connecting the connection pads and the electrode pads; and a seal covering the semiconductor chip and the wires. The semiconductor chip is distanced from the substrate while being placed inside a periphery of the substrate. The seal intervenes between the semiconductor chip and the substrate.

In another embodiment, there is provided a semiconductor device including: a substrate; a plurality of connection pads provided on the substrate; a semiconductor chip; a plurality of electrode pads provided on the semiconductor chip; and a plurality of wires electrically connecting the connection pads and the electrode pads. The semiconductor chip is suspended from the substrate while being placed inside a periphery of the substrate.

In another embodiment, there is provided a method of manufacturing a semiconductor device. The method includes the following processes. A plurality of connection pads provided on the substrate and a plurality of electrode pads provided on a semiconductor chip are electrically connected through a plurality of wires so that the semiconductor chip is suspended from the substrate with the wires. Then, an insulating resin is provided to cover the semiconductor chip and the wires and to intervene between the semiconductor chip and the substrate.

Accordingly, stress due to the difference in thermal coefficients between the semiconductor chip and the substrate decreases, thereby preventing warpage of the semiconductor device and enhancing the reliability thereof.

Further, stress focused on the external terminals provided under the four corners of the semiconductor chip decreases, thereby enhancing the reliability of secondary mounting of the semiconductor device.

Moreover, neither an adhesive nor a DAF (Die Attach film) for fixing the semiconductor chip to the substrate is necessary, thereby achieving a reduction in costs for manufacturing the semiconductor device.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a plane view illustrating a semiconductor device according to a first embodiment of the present invention;

FIG. 2 is a cross-sectional view illustrating the semiconductor device according to the first embodiment;

FIGS. 3A and 3B are, respectively, a plane view and a cross-sectional view both illustrating a wiring motherboard to be used for manufacturing the semiconductor device according to the first embodiment;

FIGS. 4A to 4D are cross-sectional views indicative of a process flow illustrating a method of manufacturing the semiconductor device according to the first embodiment;

FIGS. 5A to 5C are cross-sectional views indicative of a process flow illustrating a method of sealing the semiconductor device according to the first embodiment;

FIG. 6 is a plane view illustrating a semiconductor device according to a second embodiment of the present invention;

FIG. 7 is a cross-sectional view illustrating the semiconductor device according to the second embodiment;

FIGS. 8A and 8B are, respectively, a plane view and a cross-sectional view both illustrating a wiring motherboard to be used for manufacturing the semiconductor device according to the second embodiment;

FIGS. 9A to 9D are cross-sectional views indicative of a process flow illustrating a method of manufacturing the semiconductor device according to the second embodiment;

FIGS. 10A to 10C are cross-sectional views indicative of a process flow illustrating a method of sealing the semiconductor device according to the second embodiment;

FIG. 11 is a plane view illustrating a semiconductor device according to a third embodiment of the present invention;

FIG. 12 is a cross-sectional view illustrating the semiconductor device according to the third embodiment;

FIG. 13 is a cross-sectional view illustrating a semiconductor device according to a fourth embodiment of the present invention;

FIG. 14 is a plane view illustrating a semiconductor device according to a fifth embodiment of the present invention; and

FIG. 15 is a cross-sectional view illustrating a semiconductor device according to a fifth embodiment of the present invention.

### DETAILED DESCRIPTION OF THE PREFERRED EMBODIMENTS

The invention will now be described herein with reference to illustrative embodiments. The accompanying drawings explain a semiconductor device and a method of manufacturing the semiconductor device in the embodiments, and the size, the thickness, and the like of each illustrated portion might be different from those of each portion of an actual semiconductor device.

Those skilled in the art will recognize that many alternative embodiments can be accomplished using the teachings of the present invention and that the invention is not limited to the embodiments illustrated herein for explanatory purposes.

### First Embodiment

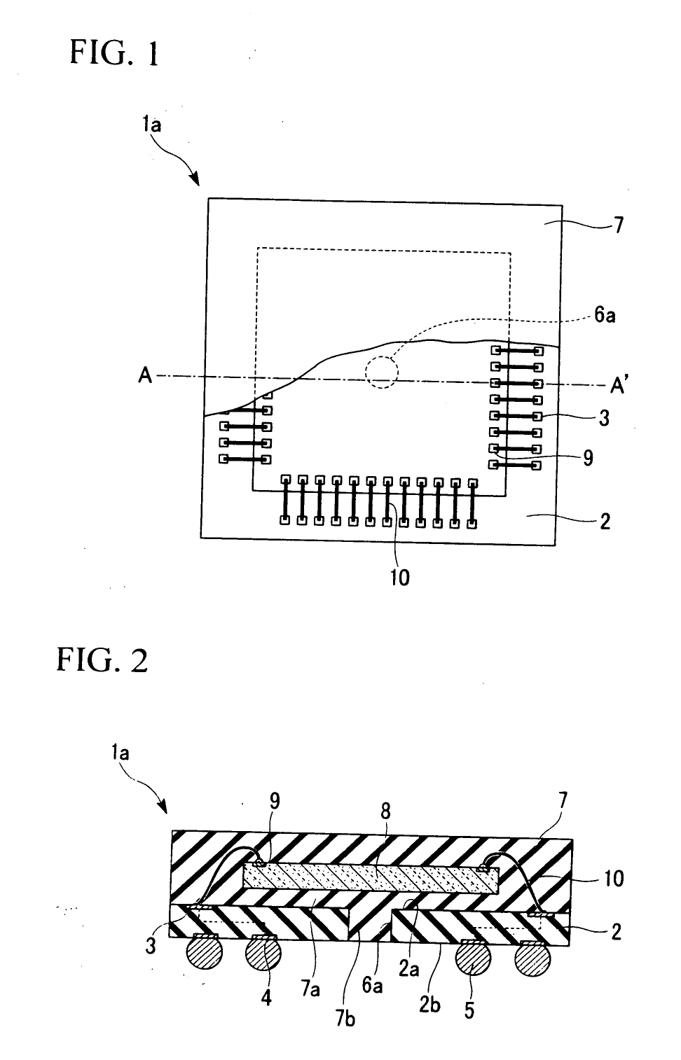

FIG. 1 is a plane view illustrating a BGA-type semiconductor device 1 a according to a first embodiment of the present invention. FIG. 2 is a cross-sectional view taken along a line A-A′ shown in FIG. 1.

The semiconductor device 1a includes: a wiring substrate 2; multiple connection pads 3 provided on a top surface 2a of the wiring substrate 2; multiple lands 4 provided on a bottom surface 2b of the wiring substrate 2 and electrically connected to the connection pads 3; a semiconductor chip 8; multiple electrode pads 9 provided on the semiconductor chip 8; wires 10 electrically connecting the connection pads 3 and the electrode pads 9; and a seal 7 that is made of insulating resin and covers at least the semiconductor chip 8 and the wires 10.

The wiring substrate 2 is generally rectangular when planarly viewed, on which given wirings are provided. The wiring substrate 2 is made of, for example, a glass epoxy substrate having a thickness of 0.25 mm. Given wirings are provided on both surfaces of the glass epoxy substrate. The wirings provided on the surfaces are respectively covered by insulating films (not shown), such as a solder resist film. The connection pads 3 are provided on portions of the top surface 2a uncovered by the insulating film. The lands 4 are provided on portions of the bottom surface 2b uncovered by the insulating film.

The connection pads 3 and the lands 4 are electrically connected by the wirings provided in the wiring substrate 2. External terminals which will be solder balls 5 are mounted on the lands 4 and aligned in a grid at a given pitch.

A through hole 6a smaller than the semiconductor chip 8 is formed in generally the center of the wiring substrate 2. Although it is explained in the first embodiment that only one through hole 6a is formed in generally the center of the wiring substrate 2, multiple through holes 6a may be formed in the wiring substrate 2 so that adhesion of the wiring substrate 2 to the seal 7 is enhanced.

The semiconductor chip 8 is provided above generally the center of the top surface 2a of the wiring substrate 2. For example, a logic circuit or a memory circuit is formed on the semiconductor chip 8. The electrode pads 9 are provided on the outer circumference of the top surface of the semiconductor chip 8 opposite to the bottom surface facing the wiring substrate 2. A passivation film (not shown) is formed on a region excluding the electrode pads 9 to protect the circuit-formed surface.

The electrode pads 9 provided on the semiconductor chip 8 are electrically connected to the connection pads 3 through conductive wires 10 made of, for example, Au or Cu.

The seal 7 is formed on the top surface 2a of the wiring substrate 2 to cover the semiconductor chip 8 and the wires 10. The seal 7 is made of, for example, thermosetting resin such as epoxy resin, and seal resin 7a included in the seal 7 intervenes between the wiring substrate 2 and the semiconductor chip 8. Thereby, the semiconductor chip 8 is upwardly distanced by, for example, approximately 10 μm from the top surface 2a of the wiring substrate 2 with the seal 7 intervening between the semiconductor chip 8 and the wiring substrate 2.

Seal resin 7b included in the seal 7 fills the through hole 6a formed in the wiring substrate 2, thereby increasing the connection area with the wiring substrate 2. Consequently, adhesion of the wiring substrate 2 to the seal 7 is enhanced.

Thus, the seal 7 intervenes between the wiring substrate 2 and the semiconductor chip 8 so that the semiconductor chip 8 is not fixed on the wiring substrate 2. Thereby, stress due to the difference in thermal expansion coefficients between the semiconductor chip 8 and the wiring substrate 2 decreases, preventing warpage of the semiconductor device 1 a and enhancing the reliability thereof.

Additionally, stress focused on the external terminals provided under the four corners of the semiconductor chip 8 decreases, thereby enhancing the reliability of secondary mounting of the semiconductor device 1a.

Further, neither an adhesive nor a DAF (Die Attach film) for fixing the semiconductor chip 8 to the wiring substrate 2 is necessary, thereby achieving a reduction in costs for manufacturing the semiconductor device 1a.

Moreover, the through hole 6a provided in the wiring substrate 2 under the semiconductor chip 8 is smaller than the semiconductor chip 8 and placed within a region where the semiconductor chip 8 is located when planarly viewed, thereby achieving miniaturization of the semiconductor device 1a.

Additionally, the seal 7 completely covers the semiconductor chip 8, thereby enhancing the humidity resistance of the semiconductor device 1a.

Further, the seal 8 fills the through hole 6a provided in the wiring substrate 2, thereby enhancing adhesion of the seal 7 to the wiring substrate 2.

Hereinafter, a method of manufacturing the semiconductor device 1a is explained.

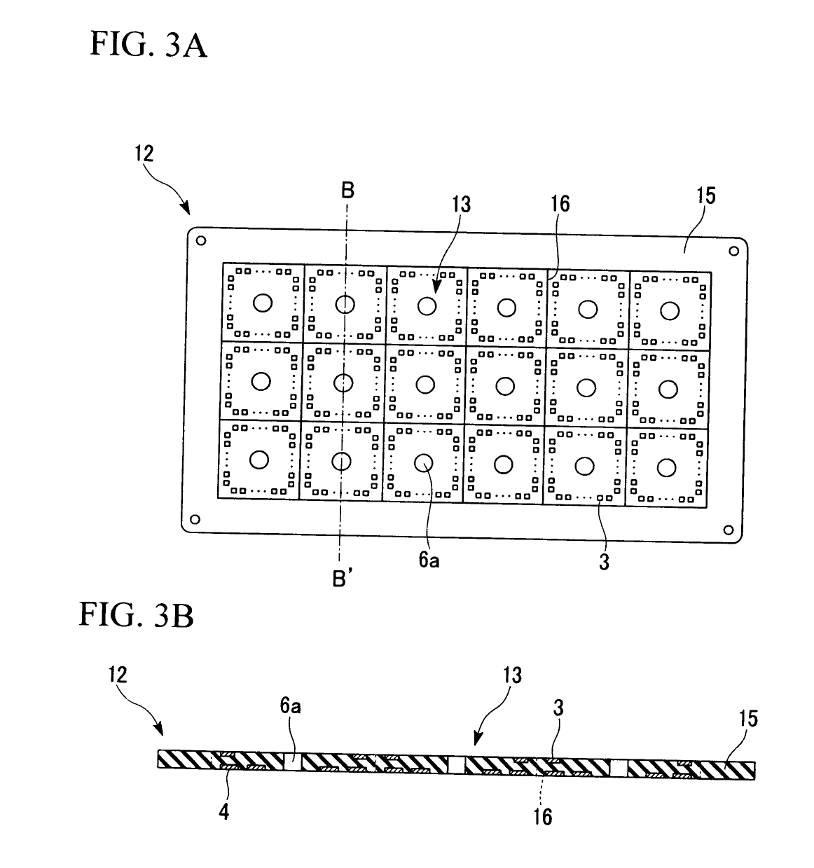

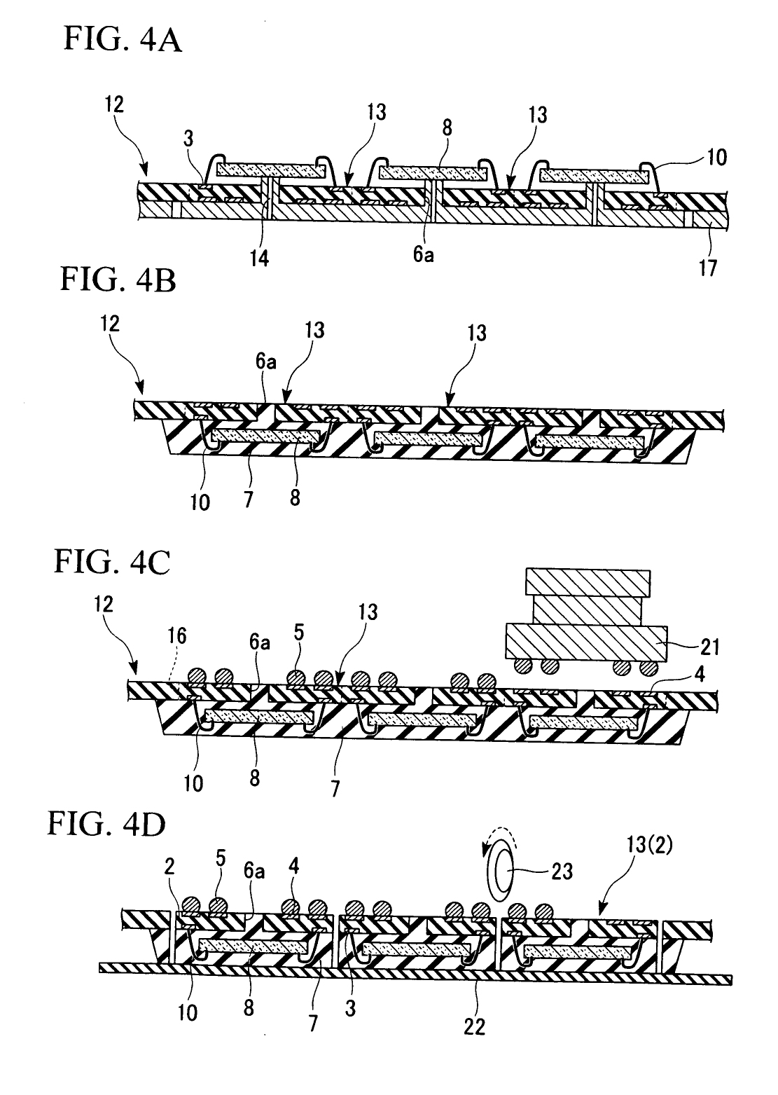

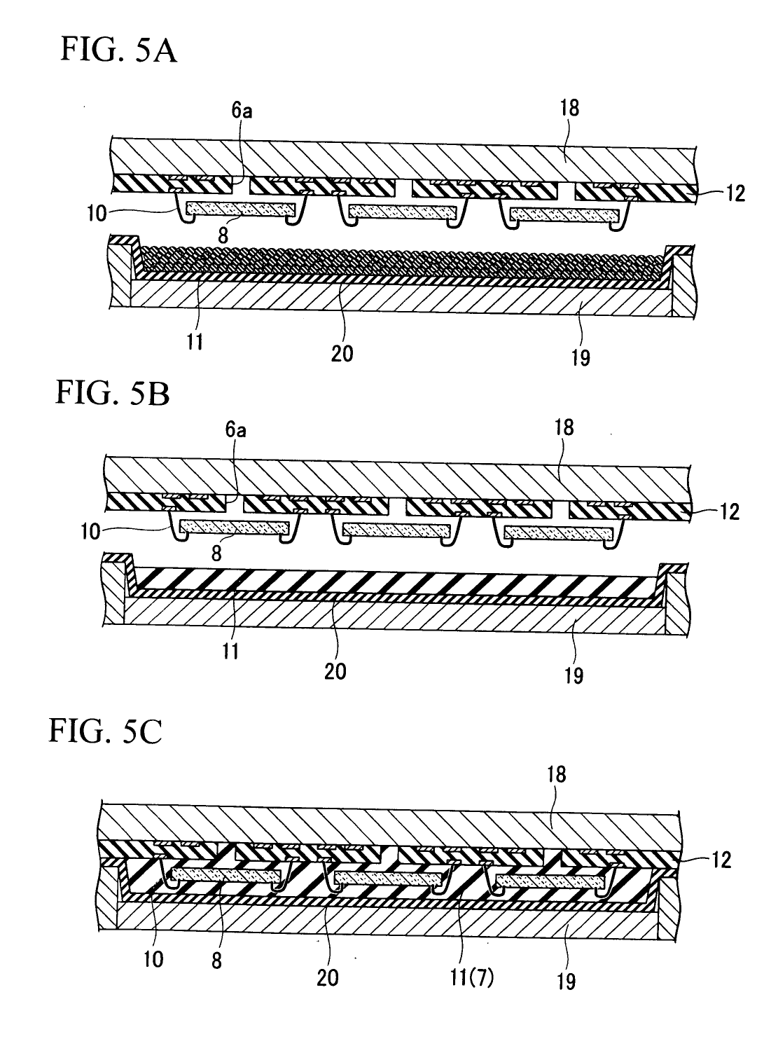

FIGS. 3A and 3B are a plane view and a cross-sectional view both illustrating a wiring motherboard 12 to be used for manufacturing the semiconductor device 1a. FIGS. 4A to 4D are cross-sectional views indicative of a process flow illustrating a method of manufacturing the semiconductor device 1a. FIGS. 5A to 5C are cross-sectional views indicative of a process flow illustrating a method of sealing the semiconductor device 1a.

The wiring motherboard 12 is processed by MAP (Mold Array Process) and includes multiple element formation units 13 aligned in a matrix. After the wiring motherboard 12 is diced, each of the element formation units 13 becomes the wiring substrate 2 and has the same structure as that of the wiring substrate 2.

The through holes 6a are provided in generally the centers of the respective element formation units 13 in the first embodiment. The through hole 6a is provided for a sucker 14 explained later to be inserted therein, a shape and the size of the through hole 6a are not limited as long as the sucker 14 can be inserted therein.

A frame 15 is provided to surround the element formation units 13 and includes positioning holes (not shown) at a given pitch for transportation and positioning. The boundaries among the element formation units are dicing lines 16.

Thus, the wiring substrate 12 is prepared as shown in FIGS. 3A and 3B.

Then, a jig 17 (not shown) including suckers 14 provided for respective through holes 6a included in the wiring motherboard 12 is prepared. As shown in FIG. 4A, the wiring motherboard 12 is fixed on the jig 17 by the suckers 14 being inserted in the through holes 6a, respectively.

Each sucker 14 is configured to protrude from the through hole 6a by a given length, for example, 10 μm or more. Then, the jig 17 on which the wiring motherboard 12 is fixed is disposed on a stage of a wire-bonding apparatus (not shown).

Then, the semiconductor chips 8 are provided on the respective suckers 14 protruding from the respective through holes 6a and fixed thereon by suction by the respective suckers 14. Thus, the semiconductor chips 8 are aligned above the element formation units 13 while being distanced from the wiring substrate 2 by approximately 10 μm.

Then, the electrode pads 9 provided on the top surface of the semiconductor chip 8 and the connection pads 3 provided on the element formation unit 13 are connected by conductive wires 10 made of, for example, Au. Specifically, one end of the wire 10 is melted into a ball shape by the wire-bonding apparatus (not shown) and then connected to the electrode pad 9 provided on the semiconductor chip 8 by ultrasonic thermocompression. Then, the wire 10 is made in a loop shape, and the other end of the wire 10 is connected to the connection pad 3 by ultrasonic thermocompression.

Although it has been explained in the first embodiment that each element formation unit 13 has one through hole 6a in generally the center thereof to hold the semiconductor chip 8, each element formation unit 13 may have multiple through holes 6a to hold the semiconductor chip 8 more stably.

Alternatively, the through holes 6a may be provided under the respective electrode pads 9 provided on the semiconductor chip 8, thereby preventing a semiconductor chip from cracking caused by a load upon wire-bonding.

Then, the jig 17 is removed with the wiring substrate 12 upside down so that the semiconductor chips 8 are suspended from the wiring motherboard 12 through the wires 10. For example, the bottom surface of the wiring motherboard 12 is fixed by suction onto an upper mold 18 of a compression mold apparatus as shown in FIG. 5A.

Then, a granular seal resin 11, for example, a thermosetting resin such as epoxy resin, is provided by a given amount into a lower mold 19 of the compression mold apparatus through a film 20. Then, the lower mold 19 is heated to a given temperature to melt the granular seal resin 11 as shown in FIG. 5B.

Then, the upper mold 18 on which the wiring motherboard 12 is fixed by suction is lowered so that the upper surface of the wiring motherboard 12 is immersed into the melted seal resin 11. Then, the seal resin 11 is compressed by the upper and lower molds 18 and 19 as shown in FIG. 5C, and thereby fills the space between the wiring motherboard 12 and the lower mold 19.

Thus, the seal resin 11 is provided by compression molding in the first embodiment without being poured from the side surfaces of the semiconductor chip 8, thereby preventing wires from being flown and enabling the seal resin 11 to seal the through holes 6a and the semiconductor chips 8 suspended from the wiring motherboard 12 through the wires 10.

Then, the seal resin 11 is thermally cured at a given temperature, for example, approximately 180° C. to form the seal 7 on the wiring motherboard 12 as shown in FIG. 4B. Since the element formation units 13 are collectively sealed, the seal 7 can efficiently be formed on the wiring motherboard 12 with better precision. Further, the semiconductor chip 8 is distanced from the wiring motherboard 12 by 10 μm or more, thereby the seal resin 11 can intervene between the semiconductor chip 8 and the wiring motherboard 12.

Then, the conductive solder balls 5 are mounted on the respective lands 4 provided in a grid on the bottom surface of the wiring motherboard 12 to form bump electrodes that will be external terminals, as shown in FIG. 4C.

Specifically, the solder balls 5 are held by a mounting apparatus 21 including multiple suckers provided at positions corresponding to those of the respective lands 4 on the wiring motherboard 12. Then, flux is applied on the solder balls 5, followed by collectively mounting the solder balls 5 onto the respective lands 4 on the element formation unit 13. After the solder balls 13 are mounted on every element formation unit 13, the wiring motherboard 12 is reflowed to form bump electrodes that will be external terminals.

Then, the wiring motherboard 12 is diced along the dicing lines 16 into multiple pieces of the element formation units 13, as shown in FIG. 4D. Specifically, the wiring motherboard 12 on the side of the seal 7 is fixed on a dicing tape 22, followed by horizontally and vertically dicing the wiring motherboard 12 along the dicing lines 16 into multiple pieces of the element formation units 13 using a dicing blade 23 of a dicing apparatus. Then, each element formation unit 13 is picked from the dicing tape 22, thereby stably obtaining the cubic semiconductor device 1a.

As explained above, the through hole 6a is provided in each element formation unit 13 on the wiring motherboard 12. The semiconductor chip 8 is held by suction by the sucker 14 protruding from the through hole 6a. The electrode pads 9 on the semiconductor chip 8 are connected to the respective connection pads 3 on the wiring substrate 2 through the wires 10. Thereby, the semiconductor chip 8 can be held above the element formation unit 13 with a gap formed therebetween.

Further, the semiconductor chips 8 are suspended at a given pitch from the element formation units 13 aligned in a grid through only the wires 10. The seal 7 is formed to cover respective surfaces of the semiconductor chips 8 by compression molding, thereby preventing the wires from being flown and enabling the semiconductor device 1 a to be efficiently manufactured.

### Second Embodiment

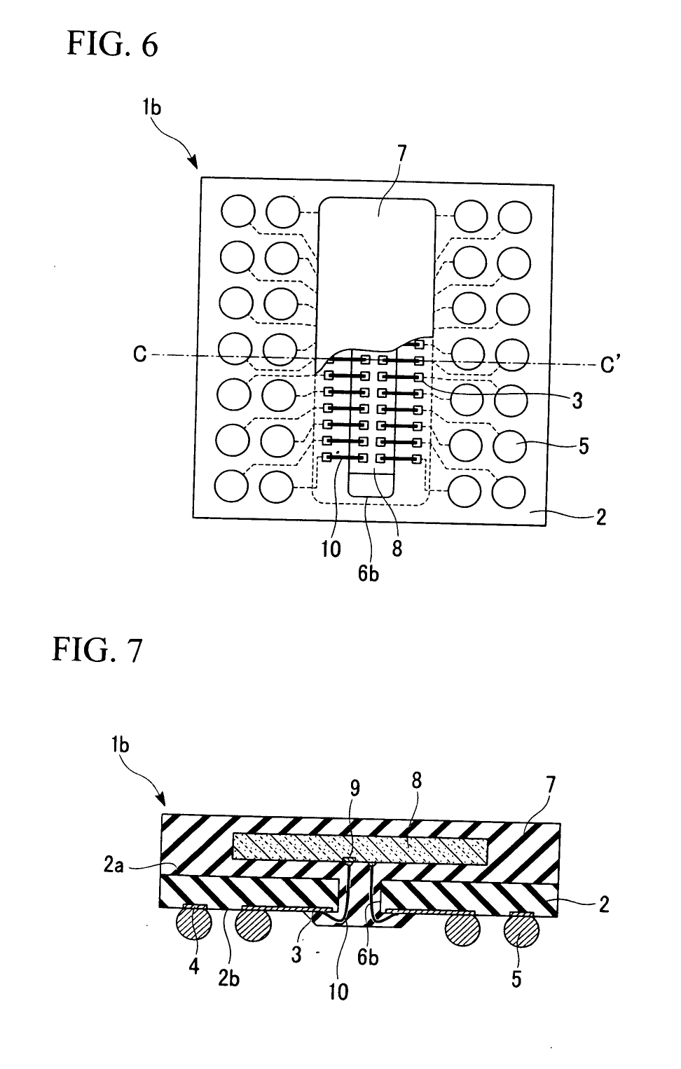

FIG. 6 is a plane view illustrating a semiconductor device 1b according to a second embodiment of the present invention. FIG. 7 is a cross-sectional view taken along a line C-C′ shown in FIG. 6. Explanations of like elements in the first embodiment are omitted here.

Similar to the first embodiment, the semiconductor device 1b includes: the generally rectangular wiring substrate 2 on which given wirings are provided; the multiple connection pads 3 provided on the bottom surface of the wiring substrate 2; and the multiple lands 4 electrically connected to the connection pads 3. A through slit 6b parallel to two opposing sides of the wiring substrate 2 is formed in generally the center of the wiring substrate 2.

The semiconductor chip 8 is provided above generally the center of the top surface 2a of the wiring substrate 2. The multiple electrode pads 9 are aligned in one or more lines along the through slit 6b on the bottom surface of the semiconductor chip 8 facing the surface 2a of the wiring substrate 2. The semiconductor chip 8 is provided above the wiring substrate 2 so that the electrode pads 9 are aligned above the through slit 6b. The electrode pads 9 provided on the semiconductor chip 8 are electrically connected to the respective connection pads 3 provided on the wiring substrate 2 through the conductive wires 10 passing through the through slit 6b.

The seal 7 is provided over the top surface 2a of the wiring substrate 2 and the through slit 6b on the bottom surface 2b thereof to cover the semiconductor chip 8 and the wires 10. The seal 7 intervenes between the wiring substrate 2 and the semiconductor chip 8, thereby the semiconductor chip 8 is held above the wiring substrate 2.

Similar effects to those of the first embodiment can be achieved in the second embodiment, and the semiconductor device 1b can be thinner.

Additionally, the rectangular through slit 6b is formed in the wiring substrate 2, thereby preventing warpage of the semiconductor device 1b.

Further, wiring patterns are formed only on one surface of the wiring substrate 2, thereby a solder resist film to cover the other surface is not necessary.

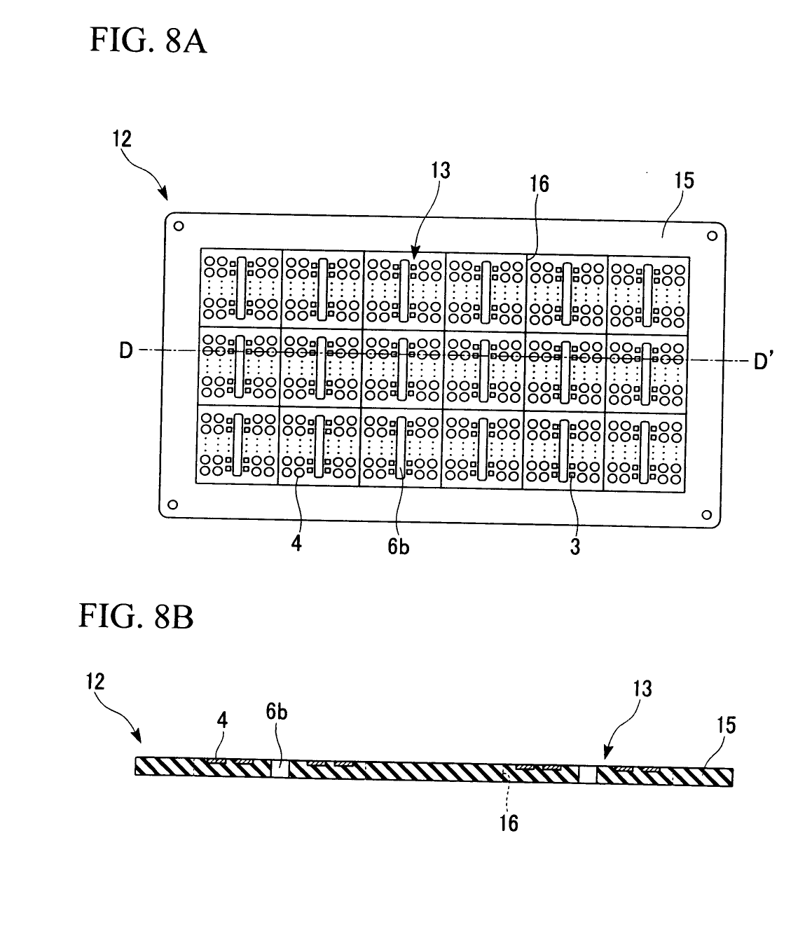

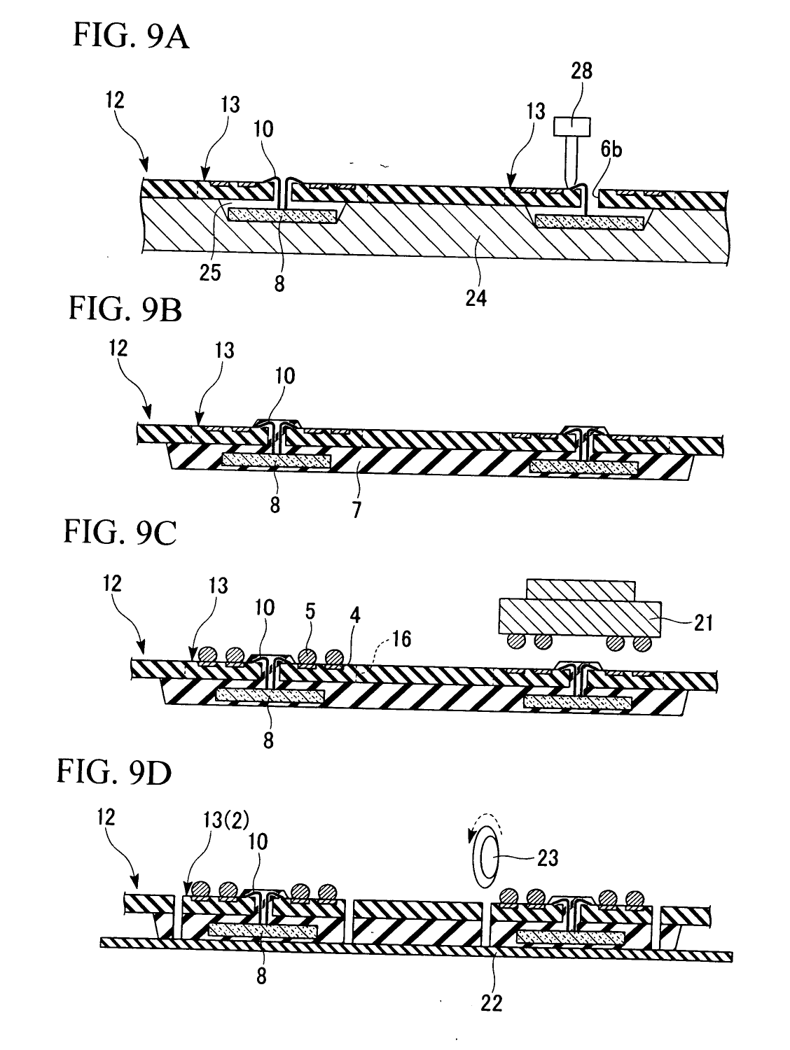

Hereinafter, a method of manufacturing the semiconductor device 1b is explained. FIGS. 8A and 8B are a plane view and a cross-sectional view both illustrating a wiring motherboard 12 to be used for manufacturing the semiconductor device 1b. FIGS. 9A to 9D are cross-sectional views indicative of a process flow illustrating a method of manufacturing the semiconductor device 1b.

Similar to the first embodiment, the wiring motherboard 12 includes the multiple element formation units 13 in a matrix, each of which will be the wiring substrate 2 after dicing and will have the same structure as that of the wiring substrate 2.

The rectangular through slit 6b is formed in generally the center of each element formation unit 13 at a position corresponding to those of the electrode pads 9 provided on the semiconductor device 1b. A shape and the size of the through slit 6b are not limited as long as the connection pads 3 provided around the through slit 6b can be electrically connected to the electrode pads 9 on the semiconductor chip 8 through wires. Thus, the wiring motherboard 12 is prepared.

Then, the wiring motherboard 12 is fixed by suction onto a stage 24 as shown in FIG. 9A. The stage 24 includes recesses 25 for the respective element formation units 13 on the wiring substrate 12, into which the respective semiconductor chips 8 are held by suction. Each of the recesses 25 has a depth such that a distance between the wiring motherboard 12 and the semiconductor chip 8 is, for example, approximately 10 μm.

The wiring substrate 12 and the semiconductor chips 8 may be separately held. Specifically, the semiconductor chips 8 may be held on a stage, and the wiring substrate 12 may be held by a sucker.

Then, the electrode pads 9 on the bottom surface of the semiconductor chip 8 are electrically connected to the respective connection pads 3 on the element formation unit 13 by the conductive wires 10 passing through the though slit 6b using a wire-bonding apparatus 28.

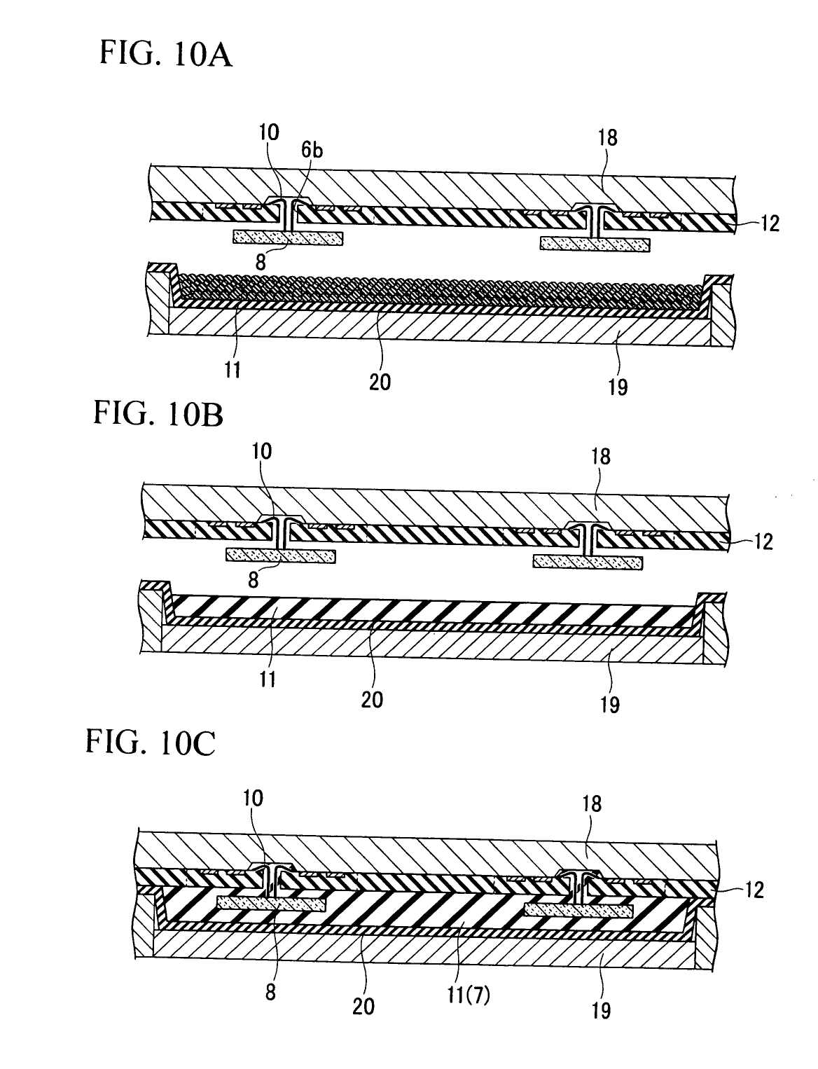

Then, the bottom surface of the wiring motherboard 12 is fixed by suction on the upper mold 18 of a compression mold apparatus as shown in FIG. 10A. The semiconductor chip 8 is suspended from the wiring motherboard 12 through the wires 10.

The upper mold 18 includes cavities respectively provided along the through slits 6b so as to hold the wiring motherboard 12 without the wires 10 being deformed.

The granular seal resin 11, for example, thermosetting resin such as epoxy resin, is provided by a given amount into the lower mold 19 of the compression mold apparatus through the film 20. The lower mold 19 is heated to a given temperature to melt the granular seal resin 11 as shown in FIG. 10B.

Then, the upper mold 18 with the wiring motherboard 12 held thereon by suction is lowered so that the upper surface of the wiring motherboard 12 is immersed into the melted seal resin 11. Then, the seal resin 11 is compressed by the upper and lower molds 18 and 19 as shown in FIG. 10C, and thereby intervenes between the wiring motherboard 12 and the lower mold 19.

Thus, the seal resin 11 is provided by compression molding without being poured from the side surfaces of the semiconductor chip 8, thereby preventing wires from being flown and enabling the seal resin 11 to seal the semiconductor chips 8 suspended from the wiring motherboard 12 through the wires 10. Further, the semiconductor chip 8 is distanced from the wiring motherboard 12 by 10 μm or more, thereby the seal resin 11 can intervene between the wiring motherboard 12 and the semiconductor chip 8.

Then, the seal resin 11 is thermally cured at a given temperature, for example, approximately 180° C. to form the seal 7 on the wiring motherboard 12 as shown in FIG. 9B. Since the element formation units 13 are collectively sealed, the seal 7 can efficiently be formed on the wiring motherboard 12 with better precision.

Then, the conductive solder balls 5 are mounted on the respective lands 4 provided in a grid on the bottom surface of the wiring motherboard 12, as shown in FIG. 9C. Then, the wiring motherboard 12 is reflowed to form external terminals.

Then, the wiring motherboard 12 is diced along the dicing lines 16 into multiple pieces of the element formation units 13, as shown in FIG. 9D. Then, each element formation unit 13 is picked from the dicing tape 22, thereby stably obtaining the cubic semiconductor device 1b.

### Third Embodiment

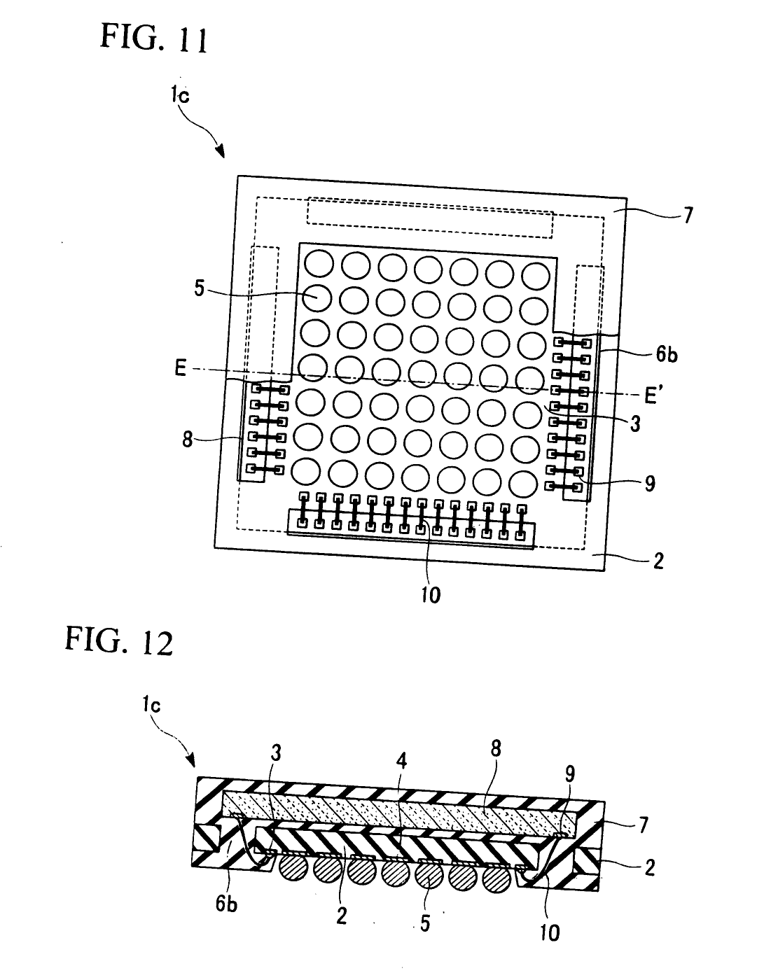

FIG. 11 is a plane view illustrating a semiconductor device 1c according to a third embodiment of the present invention. FIG. 12 is a cross-sectional view taken along a line E-E′ shown in FIG. 11.

The third embodiment is a modification of the second embodiment, and the semiconductor device 1c includes multiple electrode pads 9 provided on the semiconductor chip 8 along the four sides thereof, and through slits 6b provided in the wiring substrate 2 along the four sides thereof at positions corresponding to those of the electrode pads 9.

Multiple connection pads 3 which are provided on the bottom surface of the wiring substrate 2 and close to the through slits 6b are electrically connected to the respective electrode pads 9 on the semiconductor chip 8 through wires 10 passing through the through slots 6b. A seal 7 is provided over the upper surface 2a of the wiring substrate 2 and the through slits 6b on the bottom surface thereof to cover the semiconductor chip 8 and the wires 10.

Thus, the seal 7 intervenes between the wiring substrate 2 and the semiconductor chip 8, thereby holding the semiconductor chip 8 above the wiring substrate 2.

Similar effects as those in the second embodiment can be achieved in the third embodiment. Additionally, the electrode pads 9 are aligned along the four sides of the wiring substrate 2, thereby enabling the number of electrode pads to be increased and achieving a multi-pin semiconductor device.

Further, the electrode pads 9 aligned along the four sides of the semiconductor chip 8 are suspended by the wires 10 from the wiring substrate 2, thereby holding the semiconductor chip 8 more stably than the semiconductor device 1b of the second embodiment. Moreover, the wires 10 are connected first to the wiring substrate 2 and then to the semiconductor chip 8, thereby stably suspending the semiconductor chip 8.

### Fourth Embodiment

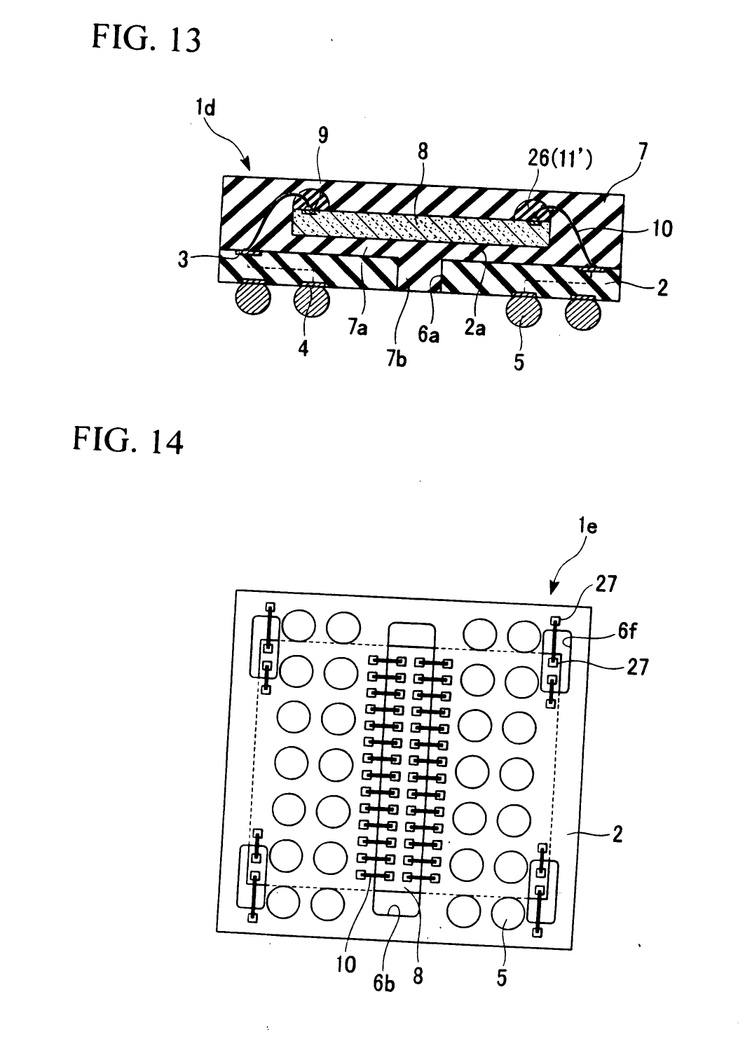

FIG. 13 is a cross-sectional view illustrating a semiconductor device Id according to a fourth embodiment of the present invention.

The fourth embodiment is a modification of the first embodiment, and the semiconductor device Id includes contact preventing portions 26 formed by potting, i.e., providing insulating seal resin 11′ on contact portions where the semiconductor chip 8 contacts the wires 10.

Thus, the contact portions are sealed by the contact preventing portions 26, thereby preventing short-circuiting caused by the wires 10 contacting side surfaces of the semiconductor chip 8.

### Fifth Embodiment

FIG. 14 is a plane view illustrating a semiconductor device 1 e according to a fifth embodiment of the present invention.

The fifth embodiment is a modification of the second embodiment, and the semiconductor device 1e includes dummy pads 27 provided around four corners of the semiconductor chip 8 and the wiring substrate 2 so that the four corners of the semiconductor chip 8 are suspended by wires 10. In other words, through holes 6f are provided around the dummy pads 27 on the wiring substrate 2 so that the dummy pads 27 on the semiconductor chip 8 and the dummy pads 27 on the wiring substrate 2 are connected by the wires 10 through the through holes 6f.

Thus, the four corners of the semiconductor chip 8 are also suspended from the wiring substrate 2 by the wires 10, thereby holding the semiconductor device 8 more stably than that suspended by the wires 10 only in the center positions.

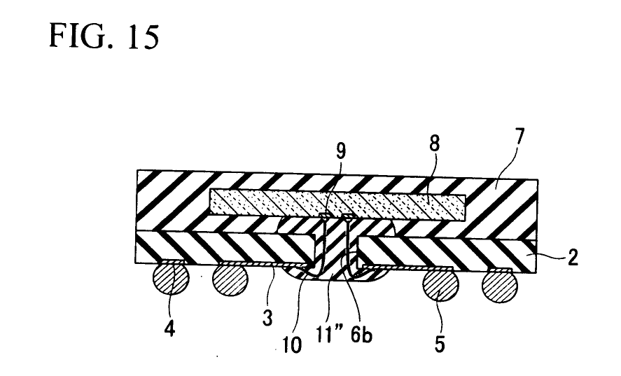

As shown in FIG. 15, insulating seal resin 11″ may be formed by potting to cover the contact portions of the semiconductor chip 8 and the through slit 6b, thereby holding the semiconductor chip more stably.

As used herein, the following directional terms “forward, rearward, above, downward, vertical, horizontal, below, and transverse” as well as any other similar directional terms refer to those directions of an apparatus equipped with the present invention. Accordingly, these terms, as utilized to describe the present invention should be interpreted relative to an apparatus equipped with the present invention.

It is apparent that the present invention is not limited to the above embodiments, but may be modified and changed without departing from the scope and spirit of the invention.

For example, the embodiments have explained the semiconductor device including one semiconductor chip on the wiring substrate, but may apply to a semiconductor device including multiple semiconductor chips aligned in parallel or mounted on multiple layers.

Further, the embodiments have explained the wiring substrate made of a glass epoxy material, but may apply to a flexible wiring substrate made of a polyamide material.

The present invention is widely applicable to semiconductor device manufacturing industries.

What is claimed is:

1. A semiconductor device, comprising:
a substrate;
a plurality of connection pads provided on the substrate;
a semiconductor chip;
a plurality of electrode pads provided on the semiconductor chip;
a plurality of wires electrically connecting the connection pads and the electrode pads; and
a seal covering the semiconductor chip and the wires,
wherein the semiconductor chip is distanced from the substrate while being placed inside a periphery of the substrate, and
the seal intervenes between the semiconductor chip and the substrate.

2. The semiconductor device according to claim 1, wherein
the substrate includes a through hole, and
the seal fills the through hole.

3. The semiconductor device according to claim 1, wherein
the substrate includes a through slit parallel to two opposing sides of the substrate in generally the center of the substrate;
the electrode pads are placed inside a periphery of the through slit;
the connection pads are provided on a surface of the substrate not facing the semiconductor chip; and
the wires connect the connection pads and the electrode pads through the through slit.

4. The semiconductor device according to claim 1, wherein the substrate includes a plurality of through slits along four sides of the substrate;
the electrode pads are placed inside a periphery of the through slits;
the connection pads are provided on a surface of the substrate not facing the semiconductor chip and close to the through slits; and
the wires connect the connection pads and the electrode pads through the through slits.

5. The semiconductor device according to claim 1, wherein each of the electrode pads is covered with an insulating resin to prevent the wires from contacting side surfaces of the semiconductor chip.

6. The semiconductor device according to claim 1, further comprising
a plurality of dummy pads provided on four corners of the semiconductor chip and the substrate,
wherein: the substrate has a plurality of through holes at four corners of the substrate;
the dummy pads are provided on a surface of the substrate not facing the semiconductor chip and close to the through holes; and
the wires connect the dummy pads on the semiconductor chip and the dummy pads on the substrate through the through holes.

7. The semiconductor device according to claim 1, wherein the seal is made of an insulating resin.

8. A semiconductor device, comprising:
a substrate;
a plurality of connection pads provided on the substrate;
a semiconductor chip;
a plurality of electrode pads provided on the semiconductor chip; and
a plurality of wires electrically connecting the connection pads and the electrode pads,
wherein the semiconductor chip is suspended from the substrate while being placed inside a periphery of the substrate.

9. The semiconductor device according to claim 8, wherein the substrate includes a through hole.

10. The semiconductor device according to claim 8, wherein
the substrate includes a through slit parallel to two opposing sides of the substrate in generally the center of the substrate;
the electrode pads are placed inside a periphery of the through slit;
the connection pads are provided on a surface of the substrate not facing the semiconductor chip; and
the wires connect the connection pads and the electrode pads through the through slit.

11. A method of manufacturing a semiconductor device, comprising:
electrically connecting a plurality of connection pads provided on the substrate and a plurality of electrode pads provided on a semiconductor chip through a plurality of wires so that the semiconductor chip is suspended from the substrate with the wires; and
providing an insulating resin to cover the semiconductor chip and the wires and to intervene between the semiconductor chip and the substrate.

12. The method according to claim 11, further comprising
forming a through hole in generally the center of the substrate before electrically connecting the plurality of connection pads,
wherein providing the insulating resin comprises providing an insulating resin to cover the semiconductor chip and the wires, fill the through hole, and intervene between the semiconductor chip and the substrate.

13. The method according to claim 11, further comprising
forming a through slit parallel to two opposing sides of the substrate in generally the center of the substrate before electrically connecting the plurality of connection pads,
wherein electrically connecting the plurality of connection pads comprises electrically connecting the connection pads and the electrode pads using the wires through the through slit so that the semiconductor chip is suspended from the substrate with the wires, and
providing the insulating resin comprises providing an insulating resin to cover the semiconductor chip and the wires and to fill the through slit.

14. The method according to claim 11, wherein
providing the insulating resin comprising:
fixing the substrate by suction onto an upper mold while the semiconductor chip is suspended from the substrate with the wires;
providing the insulating resin which is melted on a lower mold;
sandwiching the insulating resin between the upper mold and the lower mold so that the semiconductor chip is immersed into the insulating resin;
compressing the insulating resin by the upper mold and the lower mold; and
removing the upper mold and the lower mold.
